(19) United States
(12) Patent Application Publication
(10) Pub. No.: US 2021/0076496 A1
(43) Pub. Date: Mar. 11, 2021

(54) SOLDER ELECTRONIC COMPONENTS TO PRINTED CONDUCTIVE INK

(71) Applicant: Flex Ltd., Singapore (SG)

(72) Inventors: Weifeng Liu, Dublin, CA (US); William L. Uy, San Jose, CA (US); Alex Chan, San Jose, CA (US); Dongkai Shangguan, San Jose, CA (US)

(21) Appl. No.: 16/564,868

(22) Filed: Sep. 9, 2019

(51) Int. Cl. H05K 1/11; H05K 3/40; H05K 1/02; H05K 3/12; H05K 3/34; H05K 1/18; H05K 1/09

(52) U.S. Cl. CPC H05K 1/118; H05K 3/4007; H05K 1/0283; H05K 1/028; H05K 1/092; H05K 3/3436; H05K 3/3494; H05K 1/111; H05K 1/189; H05K 3/12

(57) ABSTRACT

Attaching electronic components to a substrate utilizes conductive materials to attach the components and to form traces to allow electrical connectivity between pads receiving the components. Conductive inks are non-solderable and cannot be utilized as solder pads whereas solderable inks are non-conductive. By applying a substrate with conductive ink and then selectively applying a solderable ink on the conductive ink, electronic components may be attached to a substrate that provides mechanical attachment and electrical connectivity which may also be formable or flexible.

### FIELD OF THE DISCLOSURE

The present disclosure is generally directed to electronics and more specifically to the attachment of electronic components to a substrate utilizing printed conductive ink.

### BACKGROUND

Electronic components (e.g., resistors, capacitors, microprocessors, fans, etc.) are commonly mounted to a printed circuit board (PCB) by solder to both electrically and mechanically attached the components to the PCB. Typical, PCB and flexible printed circuits (FPC) use copper traces that are not as flexible as compared to conductive ink. Conductive ink can be used to make circuitry more flexible than traditional FPC, even stretchable. Typically, anisotropic conductive film (ACF), anisotropic conductive paste (ACP), or electrically conductive adhesive (ECA) is applied to bond an electronic component to printed conductive ink. These bonding processes are not compatible with soldered interconnects that are more robust and reliable, particularly the traditional soldering reflow process. Also, conductive ink is not typically solderable, and solderable conductive ink is less flexible than non-solderable conductive ink. Soldered interconnects may also have higher bonding strength, higher throughput, lower cost, and scalable for high volume production.

### BRIEF DESCRIPTION OF THE DRAWINGS

FIG. 1 is a schematic diagram of a series of steps to form one solderable contact pad on a conductive layer in accordance with embodiments of the present disclosure;

FIG. 2 is a schematic diagram of a attaching an electronic component to a solderable contact pad in accordance with embodiments of the present disclosure;

FIG. 3 is a flowchart illustrating an example process to form a conductive layer and attaching an electronic component to the conductive layer in accordance with embodiments of the present disclosure;

FIG. 4 is a schematic diagram of a series of steps to form two solderable contact pads on a conductive layer in accordance with embodiments of the present disclosure;

FIG. 5 is a schematic diagram of attaching two electronic components to a conductive layer using two solderable contact pads in accordance with embodiments of the present disclosure;

FIG. 6 is a schematic diagram of a series of steps to form two solderable contact pads on a conductive layer in accordance with embodiments of the present disclosure;

FIG. 7 is a schematic diagram of attaching an electronic component to a conductive layer using two solderable contact pads in accordance with embodiments of the present disclosure;

FIG. 8 is a schematic diagram of a series of steps to form an opening on each of two conductive layers in accordance with embodiments of the present disclosure; and

FIG. 9 is a schematic diagram of attaching an electronic component to two conductive layers using two solderable contact pads in accordance with embodiments of the present disclosure described herein;

### DETAILED DESCRIPTION

Embodiments of the present disclosure will be described in connection to electronics. While embodiments are generally directed to electronics and more specifically the attachment of electronic components to a substrate utilizing printed conductive ink utilizing a soldering process, it should be appreciated that other embodiments may be utilized without departing from the scope of the disclosure. In addition to attaching electronic components to PCB and creating an FPC, electronic components may be attached to or formed on wearable fabrics to create wearable electronics. Embodiments may also include mounting components utilizing a through-hole mounting process rather than a soldering process as described herein.

While conductive ink is not typically solderable, and solderable conductive ink is less flexible than non-solderable conductive ink, combining solderable and non-solderable conductive inks allow soldered interconnects to be formed. In one embodiment, the method includes conductive ink printing process to apply a conductive ink layer to a nonconductive substrate, a dielectric ink printing, solderable pads fabrication, stencil printing solder paste, attaching one or more components, and a reflow process to create soldered interconnects between the solderable pads, also called contact pads, and electrical connection points of one or more electronic components.

As used herein, solderability is a measure of the ease with which a soldered joint can be made using the solder material. Solderability requires wetting (low contact angle) of the substrate by the solder, as is known in the art. (See, for example, https://en.wikipedia.org/wiki/Wetting, which is herein incorporated by reference).

For solderable ink, as used herein, a solder paste (e.g., SnBiAg, SAC105, SAC305), when melted at sufficiently high temperature, will spread and wet the pads, such as those made through screen printing the solderable ink, such as when applied in paste form at a lower, below melting point temperature, and after melting forms a permanent interconnect through alloying (intermetallic) with metals (such as copper, silver plated copper) in the solderable ink. Non-solderable ink is on the contrary and has one or more properties of, cannot wet, cannot alloy, incorporates a metal (like silver) in the ink which will dissolve in the molten solder, and/or the polymer matrix in the ink cannot sustain the sufficiently high temperature for reflow. Accordingly, non-solderable ink cannot form a permanent conductive bond or interconnect.

Conductive inks are non-solderable (commonly using silver or carbon particles), most are proprietary formulas and the details of the formulas are unknown. In one example, silver coated copper particles are used in the ink. If only silver particles are used, silver will be dissolved in the solder quickly and cannot form a good bonding. When silver coated copper is used, solder will form a bonding with copper particles at the same time copper particles remain embedded in the ink polymer matrix.

In summary, this invention is to use conductive ink to make flexible and stretchable traces and/or pads and use selective plating to make the pads (or non-solderable ink) solderable. Accordingly, general embodiments described herein are directed to making: 1) flexible circuit using conductive ink to make it (flexible, stretchable, and conformable), 2) flexible circuit with solderable pads through selective plating, 3) flexible circuit using reflow process to solder components to substrate, or 4) combinations of the foregoing. As will be described herein, embodiments directed towards a trace (a conductive pathway between pads) and a pad (a geometry to receive a conductive portion of a component for attachment during reflow or other soldering operation, can be used interchangeably depending on the application. In other words, while not common, certain embodiments disclosed herein would allow for certain embodiments describing the use and application of conductive and non-conductive ink for a trace or pad to be used in the other.

The nonconductive substrate is an ink printing carrier having a surface for receiving conductive ink, non-conductive ink, or other types of ink. The nonconductive substrate includes thermoplastic polyurethane (TPU), polydimethylsiloxane (PDMS), polyethylene terephthalate (PET), polyvinylchloride (PVC), polycarbonate (PC), polyethylene (PE), polypropylene (PP), polyimide (PI), polyethylene naphthalate (PEN), polyetherimide (PEI), along with various fluoropolymers (FEP), olefin and/or other polymer. In some embodiments, the substrate is paper or fabric.

Materials in the conductive ink includes silver (Ag), gold (Au), copper (Cu), nickel (Ni), palladium (Pd), platinum (Pt), alloys, composites, and mixtures thereof. Applying the conductive ink includes one or more of dispensing, flat bed screen printing, roll to roll screen printing, gravure printing, inkjet printing, aerosol jet printing, or flexography printing. Forming the opening in the conductive layer includes one or more of mechanical drilling, laser drilling, etching, or selectively applying conductive ink.

Applying the non-conductive dielectric layer includes one or more of spin coating, laminating, dispensing, depositing, flat bed screen printing, roll to roll screen printing, gravure printing, inkjet printing, aerosol jet printing, or flexography printing. Forming the opening in the non-conductive dielectric layer includes one or more of selective applying a dielectric ink, mechanical drilling, laser drilling, or etching.

Solderable pads may be fabricated through selective plating process, e.g., electrolytic or electroless process, or by printing solderable conductive ink. Electroless plating may require the use of a precursor, where the use of a precursor and the materials in the precursor depend on the conductive ink used. Typically, the precursor is a palladium based material, such as palladium chloride, that may be printed onto the contact pads to activate the contact pad surface. Electroless plating using electroless plating solutions to plate different metals (e.g., a single layer or multilayer, electroless copper, electroless nickel immersion gold, electroless silver, immersion tin). By making the pads solderable, the electronic components can be soldered to the ink printed substrates using a reflow process, where the reflow profile will depend on the solder paste material used. Typical solder paste includes SAC 305, SAC105, other SAC solder alloys, SnBi, and SnBiAg.

In some embodiments, one or more conductive ink layers and one or more contact pads are formed on each of the conductive ink layers. One or more nonconductive dielectric layers may also separate the conductive ink layers. The contact pads may be separated by the non-conductive dielectric layer.

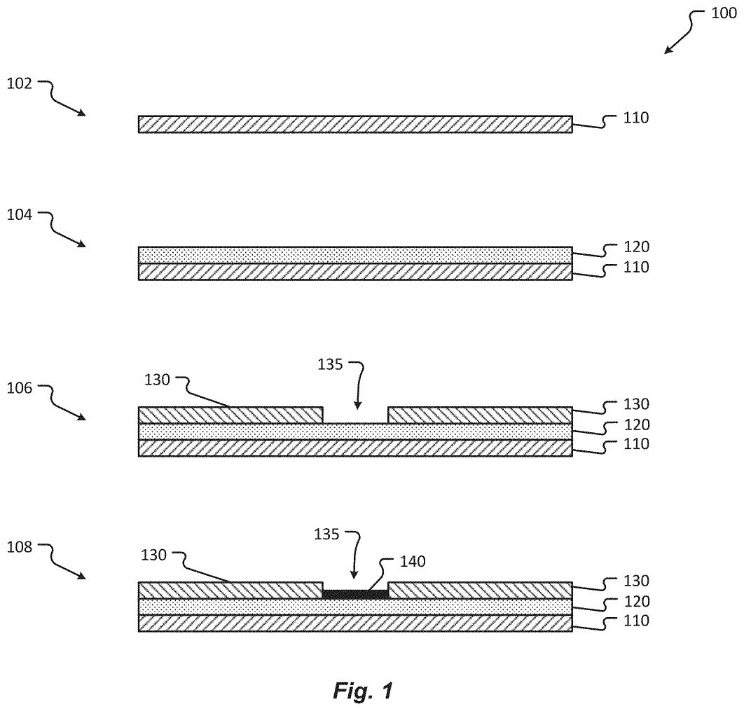

FIG. 1 is a schematic diagram 100 of a series of steps to form one solderable contact pad on a conductive layer in accordance with embodiments of the present disclosure. Schematic diagram 100 is not drawn to scale. In diagram 102, the non-conductive substrate 110 is applied or formed. In diagram 104, a conductive ink is applied to selected portions of the non-conductive substrate 110 to form the conductive layer 120. The conductive layer 120 may require curing or drying. In diagram 106, a non-conductive dielectric is applied to portions of the conductive layer 120 and portions of the non-conductive substrate 110 to form a non-conductive dielectric layer 130 with an opening 135 over the conductive layer 120. In diagram 108, the solderable contact pad 140 is formed on the conductive layer 120 in the opening 135. The solderable contact pad may be fabricated through a selective plating process, e.g., electrolytic or electroless process, or by printing solderable conductive ink. The contact pad 140 may include portions of the bottom and walls in the opening 135, where the bottom is a portion of the conductive layer 120 and the walls may be portions of the conductive layer 120 and portions of the non-conductive dielectric layer 130. The solderable conductive ink may require curing or drying.

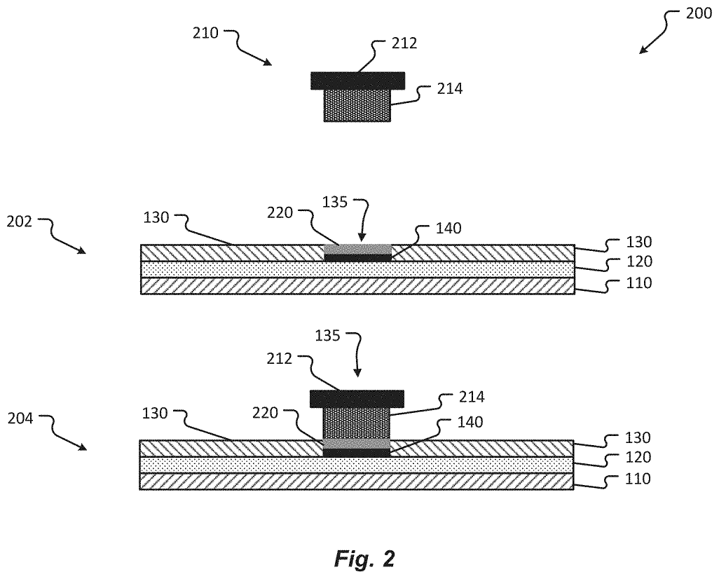

FIG. 2 is a schematic diagram 200 of a attaching an electronic component 210 to a conductive layer using one solderable contact pad in accordance with embodiments of the present disclosure. Electronic component 210 includes an electronic portion 212 and an electrical connection point 214. In diagram 202, the solder paste 220 is applied to selected portions of the contact pad 140 in the opening 135 and/or the electrical connection point 214. The solder paste 220 may also cover potions of the wall of the opening 135. In diagram 204, the electrical connection point 214 of the electronic component 210 is placed in a position adjacent to the contact pad 140 with the solder paste 220 touching the contract pad 140 and the electrical connection point 214. The solder paste 220 is heated to electrically couple the electrical connection point 214 to the contact pad 140.

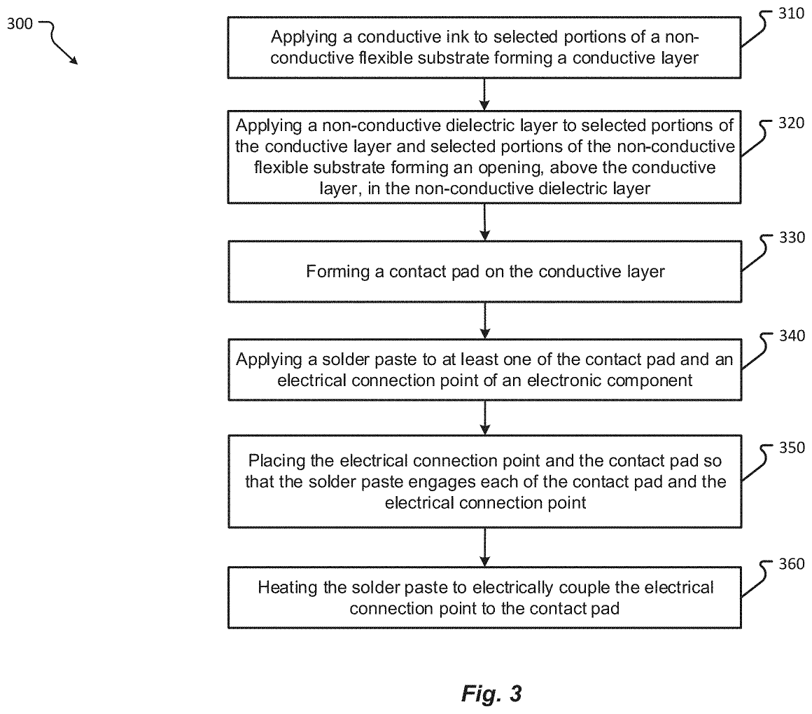

FIG. 3 is a flowchart 300 illustrating an example process to form a conductive layer and attaching an electronic component to the conductive layer in accordance with embodiments of the present disclosure. Flowchart 300 begins at step 310. In step 310, a conductive ink is applied to selected portions of a non-conductive flexible substrate forming a conductive layer, as depicted in diagram 104 in FIG. 1. Flowchart 300 transitions to step 320 where a non-conductive dielectric layer is applied to selected portions of the conductive layer and selected portions of the non-conductive flexible substrate forming an opening, above the conductive layer, in the non-conductive dielectric layer, as depicted in 106 in FIG. 1. Flowchart 300 transitions to step 330 where a contact pad is formed on the conductive layer, as depicted in diagram 108 in FIG. 1. Flowchart 300 transitions to step 340 where a solder paste is applied to at least one of the contact pad and an electrical connection point of an electronic component, as depicted in diagram 202 in FIG. 2. Flowchart 300 transitions to step 350 where the electrical connection point and the contact pad are placed so that the solder paste engages each of the contact pad and the electrical connection point, as depicted in 204 in FIG. 2. Flowchart 300 transitions to step 360 where the solder paste is heated to electrically couple the electrical connection point of the electrical component to the contact pad.

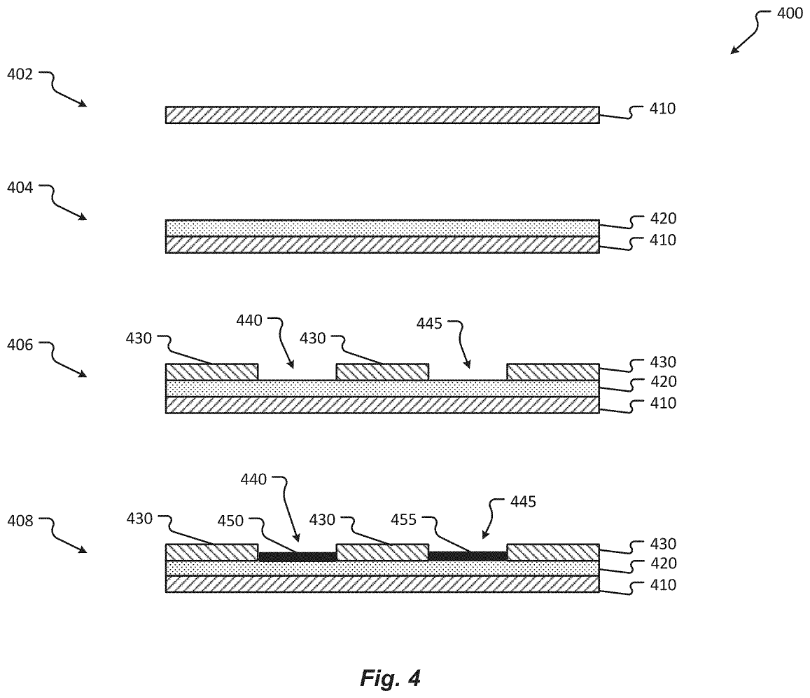

FIG. 4 is a schematic diagram 400 of a series of steps to form two solderable contact pads on a conductive layer in accordance with embodiments of the present disclosure. Schematic diagram 400 is not drawn to scale. In diagram 402, the non-conductive substrate 410 is applied or formed. In diagram 404, a conductive ink is applied to portions of the non-conductive substrate 410 to form the conductive layer 420. The conductive layer 420 may require curing or drying. In diagram 406, a non-conductive dielectric is applied to portions of the conductive layer 420 and portions of the non-conductive substrate 410 to form a non-conductive dielectric layer 430 with an opening 440 and an opening 335 over the conductive layer 420. In diagram 408, the solderable contact pad 450 and solderable contact pad 455 are formed on the conductive layer 420 in the opening 440 and the opening 445, respectively. The solderable contact pads may be fabricated through a selective plating process, e.g., electrolytic or electroless process, or by printing solderable conductive ink. The contact pad 450 and contact pad 455 may include portions of the bottom and walls in the opening 440 and opening 445, where the bottom is a portion of the conductive layer 420 and the walls may be portions of the conductive layer 420 and portions of the non-conductive dielectric layer 430. The solderable conductive ink may require curing or drying.

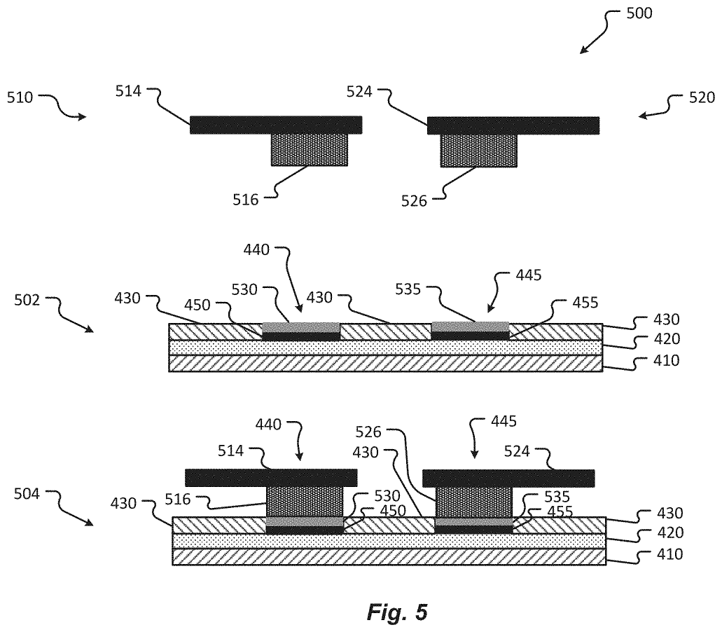

FIG. 5 is a schematic diagram 500 of attaching two electronic components to a conductive layer using two solderable contact pads in accordance with embodiments of the present disclosure. Schematic diagram 500 is not drawn to scale. Electronic component 510 includes an electronic portion 514 and an electrical connection point 516, and electronic component 520 includes an electronic portion 524 and an electrical connection point 526. In diagram 502, the solder paste 530 is applied to portions of the contact pad 450 in the opening 440 and/or the electrical connection point 516, the solder paste 535 is applied to portions of the contact pad 455 in the opening 445 and/or the electrical connection point 526. The solder paste 530 and the solder paste 535 may also cover potions of the wall of the opening 440 and the opening 445, respectively. In diagram 504, the electrical connection point 516 of the electronic component 510 is placed in a position adjacent to the contact pad 450 with the solder paste 530 touching the contract pad 450 and the electrical connection point 516. Also, the electrical connection point 526 of the electronic component 520 is placed in a position adjacent to the contact pad 455 with the solder paste 535 touching the contract pad 455 and the electrical connection point 526. The solder paste 530 is heated to electrically couple the electrical connection point 516 to the contact pad 450. Also, the solder paste 535 is heated to electrically couple the electrical connection point 526 to the contact pad 455.

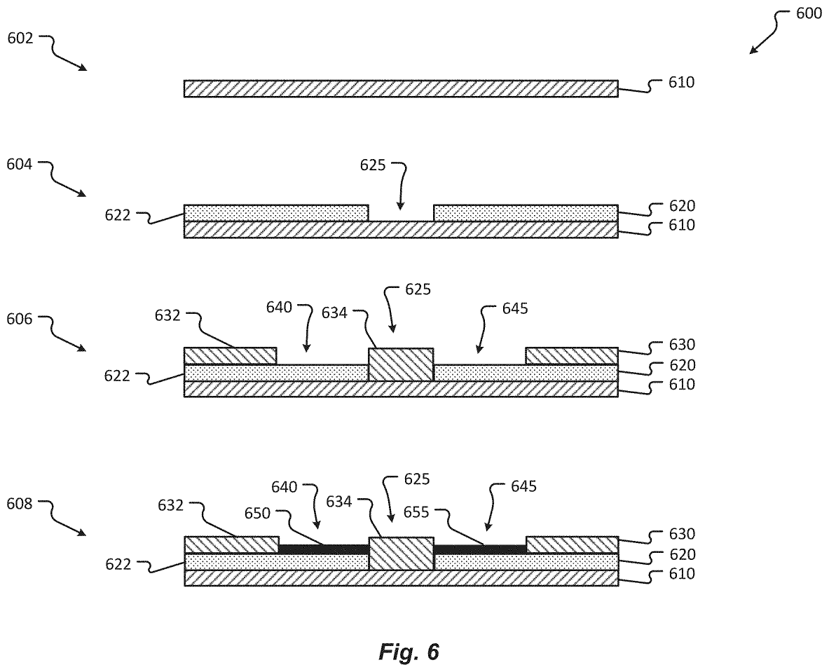

FIG. 6 is a schematic diagram 600 of a series of steps to form two solderable contact pads on a conductive layer in accordance with embodiments of the present disclosure. Schematic diagram 600 is not drawn to scale. In diagram 602, the non-conductive substrate 610 is applied or formed. In diagram 604, a conductive ink is applied to portions of the non-conductive substrate 610 to form the conductive layer 620 and the conductive layer 622. The conductive layer 620 and conductive layer 622 may require curing or drying. In diagram 606, a non-conductive dielectric layer 630 comprising a non-conductive dielectric layers 632, 634 is applied to selected portions of the conductive layer 620, portions of the conductive layer 622, and portions of the non-conductive substrate 610. The non-conductive dielectric layer 632, and the non-conductive dielectric layer 634 form opening 640 and an opening 645 over the conductive layer 622 and conductive layer 620, respectively. In diagram 608, the solderable contact pad 650 and solderable contact pad 655 are formed on the conductive layer 622 in the opening 640 and the conductive layer 620 in the opening 645, respectively. The solderable contact pads may be fabricated through a selective plating process, e.g., electrolytic or electroless process, or by printing solderable conductive ink. The contact pad 650 and contact pad 655 may include portions of the bottom and walls in the opening 640 and the opening 645, respectively. The solderable conductive ink may require curing or drying.

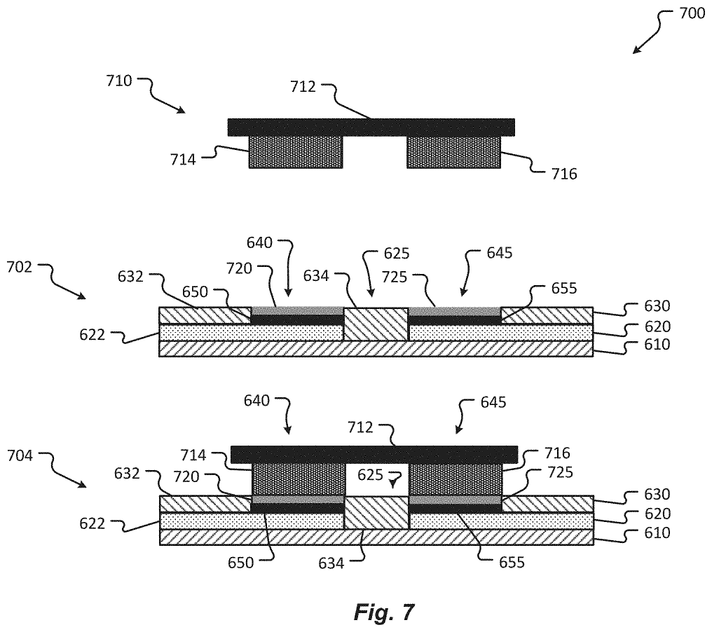

FIG. 7 is a schematic diagram 700 of attaching an electronic component to a conductive layer using two solderable contact pads in accordance with embodiments of the present disclosure. Schematic diagram 700 is not drawn to scale. Electronic component 710 includes an electronic portion 712, an electrical connection point 714, and an electrical connection point 716. In diagram 702, the solder paste 720 is applied to portions of the contact pad 650 in the opening 640 and/or the electrical connection point 714, the solder paste 725 is applied to portions of the contact pad 655 in the opening 645 and/or the electrical connection point 716. The solder paste 720 and the solder paste 725 may also cover potions of the wall of the opening 640 and the opening 645, respectively. In diagram 704, the electrical connection point 714 of the electronic component 710 is placed in a position adjacent to the contact pad 650 with the solder paste 720 touching the contract pad 650 and the electrical connection point 714. Also, the electrical connection point 716 of the electronic component 710 is placed in a position adjacent to the contact pad 655 with the solder paste 725 touching the contract pad 655 and the electrical connection point 716. The solder paste 720 is heated to electrically couple the electrical connection point 714 to the contact pad 650. Also, the solder paste 725 is heated to electrically couple the electrical connection point 716 to the contact pad 655.

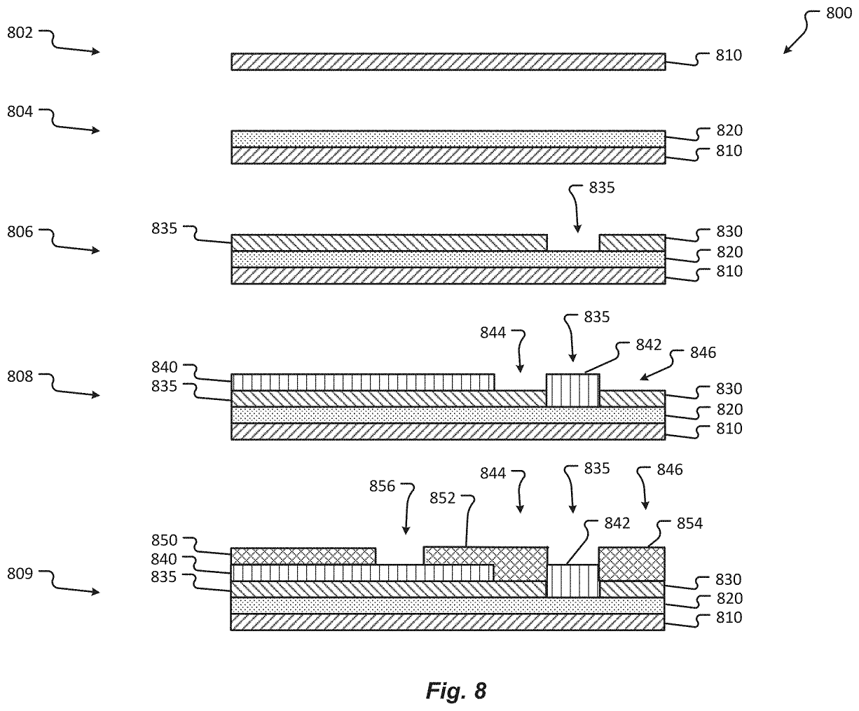

FIG. 8 is a schematic diagram of a series of steps to form an opening on each of two conductive layers in accordance with embodiments of the present disclosure. Schematic diagram 800 is not drawn to scale. In diagram 802, the non-conductive substrate 810 is applied or formed. In diagram 804, a conductive ink is applied to portions of the non-conductive substrate 810 to form the first conductive layer 820. In diagram 806, a non-conductive dielectric is applied to selected portions of the first conductive layer 820 and portions of the non-conductive substrate 810 to form the non-conductive dielectric layer 830, the non-conductive dielectric layer 835, and the opening 835 over the first conductive layer 820. In diagram 808, a conductive ink is applied to portions of the non-conductive dielectric layer 830 and non-conductive dielectric layer 835 to form the second conductive layer 840 and 842, and the opening 844 over the conductive layer 835. The first conductive layer 820, and the second conductive layer 840 and 842 may require curing or drying. In diagram 809, a non-conductive dielectric is applied to selected portions of the second conductive layer 840 and non-conductive dielectric layer 830 and 835 to form the non-conductive dielectric layer 850, 852, and 854, and the opening 856 over the second conductive layer 840. The conductive layer 820 and conductive layer 840 may require curing or drying.

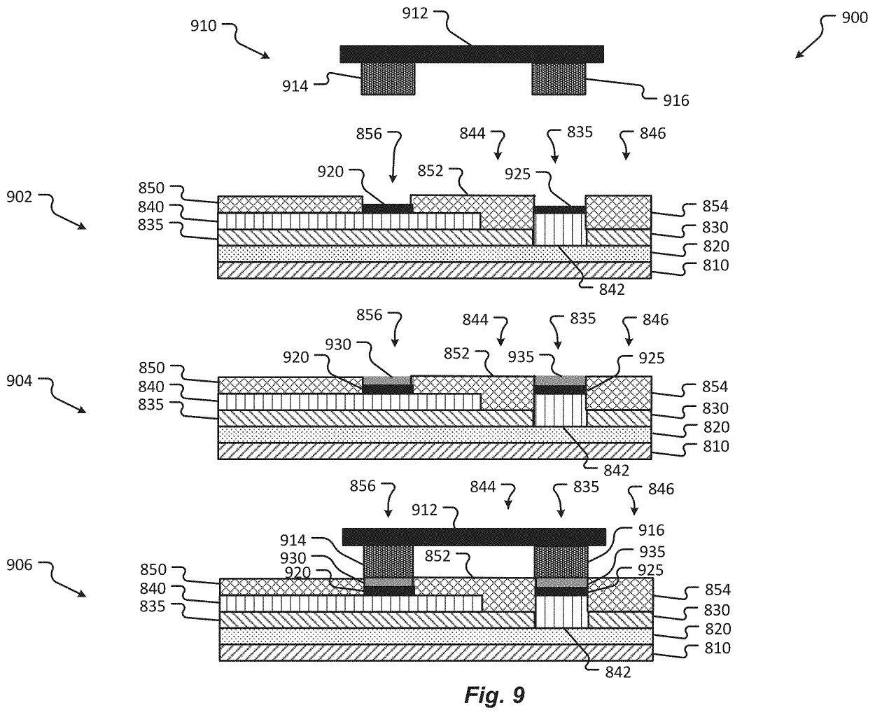

FIG. 9 is a schematic diagram of attaching an electronic component to two conductive layers using two solderable contact pads in accordance with embodiments of the present disclosure described herein. Schematic diagram 900 is not drawn to scale. Electronic component 910 includes an electronic portion 912, an electrical connection point 914, and an electrical connection point 916. In diagram 902, the solderable contact pad 920 and solderable contact pad 925 are formed on the conductive layer 840 in the opening 856 and the conductive layer 842 in the opening 835, respectively. The solderable contact pads may be fabricated through a selective plating process, e.g., electrolytic or electroless process, or by printing solderable conductive ink. The contact pad 920 and contact pad 925 may include portions of the bottom and walls in the opening 856 and the opening 835, respectively. The solderable conductive ink may require curing or drying. In diagram 904, the solder paste 930 is applied to portions of the contact pad 920 in the opening 856 and/or the electrical connection point 914, the solder paste 935 is applied to portions of the contact pad 925 in the opening 835 and/or the electrical connection point 916. The solder paste 930 and the solder paste 935 may also cover potions of the wall of the opening 856 and the opening 835, respectively. In diagram 906, the electrical connection point 914 of the electronic component 910 is placed in a position adjacent to the contact pad 920 with the solder paste 930 touching the contract pad 920 and the electrical connection point 914. Also, the electrical connection point 916 of the electronic component 910 is placed in a position adjacent to the contact pad 925 with the solder paste 935 touching the contract pad 925 and the electrical connection point 916. The solder paste 930 is heated to electrically couple the electrical connection point 914 to the contact pad 920. Also, the solder paste 935 is heated to electrically couple the electrical connection point 916 to the contact pad 925.

The phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” means A alone, B alone, C alone, A and B together, A and C together, B and C together, or A, B, and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium,” as used herein, refers to any tangible storage that participates in providing instructions to a microprocessor for execution. Such a medium may take many forms, including, but not limited to, non-volatile media, volatile media, and transmission media. Non-volatile media includes, for example, NVRAM, or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a CD-ROM, any other optical medium, punch cards, paper tape, any other physical medium with patterns of holes, a RAM, a PROM, an EPROM, a FLASH-EPROM, a solid-state medium like a memory card, any other memory chip or cartridge, or any other medium from which a computer can read. When the computer-readable media is configured as a database, it is to be understood that the database may be any type of database, such as relational, hierarchical, object-oriented, and/or the like. Accordingly, the disclosure is considered to include a tangible storage medium and prior art-recognized equivalents and successor media, in which the software implementations of the present disclosure are stored.

While machine-executable instructions may be stored and executed locally to a particular machine (e.g., personal computer, mobile computing device, laptop, etc.), it should be appreciated that the storage of data and/or instructions and/or the execution of at least a portion of the instructions may be provided via connectivity to a remote data storage and/or processing device or collection of devices, commonly known to as “the cloud,” but may include a public, private, dedicated, shared and/or other service bureau, computing service, and/or “server farm.”

In the foregoing description, for the purposes of illustration, methods were described in a particular order. It should be appreciated that in alternate embodiments, the methods may be performed in a different order than that described without departing from the scope of the embodiments. It should also be appreciated that the methods described above may be performed as algorithms executed by hardware components (e.g., circuitry) purpose-built to carry out one or more algorithms or portions thereof described herein. In another embodiment, the hardware component may comprise a general-purpose microprocessor (e.g., CPU, GPU) that is first converted to a special-purpose microprocessor. The special-purpose microprocessor then having had loaded therein encoded signals causing the, now special-purpose, microprocessor to maintain machine-readable instructions to enable the microprocessor to read and execute the machine-readable set of instructions derived from the algorithms and/or other instructions described herein. The machine-readable instructions utilized to execute the algorithm(s), or portions thereof, are not unlimited but utilize a finite set of instructions known to the microprocessor. The machine-readable instructions may be encoded in the microprocessor as signals or values in signal-producing components and included, in one or more embodiments, voltages in memory circuits, configuration of switching circuits, and/or by selective use of particular logic gate circuits. Additionally or alternative, the machine-readable instructions may be accessible to the microprocessor and encoded in a media or device as magnetic fields, voltage values, charge values, reflective/non-reflective portions, and/or physical indicia.

In another embodiment, the microprocessor further comprises one or more of a single microprocessor, a multi-core processor, a plurality of microprocessors, a distributed processing system (e.g., array(s), blade(s), server farm(s), “cloud”, multi-purpose processor array(s), cluster(s), etc.) and/or may be co-located with a microprocessor performing other processing operations. Any one or more microprocessor may be integrated into a single processing appliance (e.g., computer, server, blade, etc.) or located entirely or in part in a discrete component connected via a communications link (e.g., bus, network, backplane, etc. or a plurality thereof).

Examples of general-purpose microprocessors may comprise, a central processing unit (CPU) with data values encoded in an instruction register (or other circuitry maintaining instructions) or data values comprising memory locations, which in turn comprise values utilized as instructions. The memory locations may further comprise a memory location that is external to the CPU. Such CPU-external components may be embodied as one or more of a field-programmable gate array (FPGA), read-only memory (ROM), programmable read-only memory (PROM), erasable programmable read-only memory (EPROM), random access memory (RAM), bus-accessible storage, network-accessible storage, etc.

These machine-executable instructions may be stored on one or more machine-readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

Also, it is noted that the embodiments were described as a process, which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in the figure. A process may correspond to a method, a function, a procedure, a subroutine, a subprogram, etc. When a process corresponds to a function, its termination corresponds to a return of the function to the calling function or the main function.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine-readable medium, such as a storage medium. A microprocessor(s) may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

Embodiments herein comprising software are executed, or stored for subsequent execution, by one or more microprocessors and are executed as executable code. The executable code being selected to execute instructions that comprise the particular embodiment. The instructions executed being a constrained set of instructions selected from the discrete set of native instructions understood by the microprocessor and, prior to execution, committed to microprocessor-accessible memory. In another embodiment, human-readable “source code” software, prior to execution by the one or more microprocessors, is first converted to system software to comprise a platform (e.g., computer, microprocessor, database, etc.) specific set of instructions selected from the platform's native instruction set.

While illustrative embodiments of the disclosure have been described in detail herein, it is to be understood that the inventive concepts may be otherwise variously embodied and employed, and that the appended claims are intended to be construed to include such variations, except as limited by the prior art.

The ensuing description provides embodiments only and is not intended to limit the scope, applicability, or configuration of the claims. Rather, the ensuing description will provide those skilled in the art with an enabling description for implementing the embodiments. It will be understood that various changes may be made in the function and arrangement of elements without departing from the spirit and scope of the appended claims.

Any reference in the description comprising an element number, without a subelement identifier when a subelement identifier exists in the figures, when used in the plural, is intended to reference any two or more elements with a like element number. When such a reference is made in the singular form, it is intended to reference one of the elements with the like element number without limitation to a specific one of the elements. Any explicit usage herein to the contrary or providing further qualification or identification shall take precedence.

The exemplary systems and methods of this disclosure will also be described in relation to analysis software, modules, and associated analysis hardware. However, to avoid unnecessarily obscuring the present disclosure, the following description omits well-known structures, components, and devices, which may be omitted from or shown in a simplified form in the figures or otherwise summarized.

For purposes of explanation, numerous details are set forth in order to provide a thorough understanding of the present disclosure. It should be appreciated, however, that the present disclosure may be practiced in a variety of ways beyond the specific details set forth herein.

The terms “determine,” “calculate,” and “compute,” and variations thereof, as used herein, are used interchangeably and include any type of methodology, process, mathematical operation, or technique.

The term “module,” as used herein, refers to any known or later-developed hardware, software, firmware, artificial intelligence, fuzzy logic, or combination of hardware and software that is capable of performing the functionality associated with that element. Also, while the disclosure is described in terms of exemplary embodiments, it should be appreciated that other aspects of the disclosure can be separately claimed.

What is claimed is:

1. A method for forming a contact pad on a non-conductive flexible substrate, comprising:
applying a conductive ink to a selected portion of the non-conductive flexible substrate forming a conductive layer;
applying a non-conductive dielectric layer to a selected portion of the conductive layer and to a selected portion of the non-conductive flexible substrate forming an opening, above the conductive layer, in the non-conductive dielectric layer; and
forming the contact pad on the conductive layer.

2. The method of claim 1, wherein one or more of the non-conductive flexible substrate, the conductive layer, or the non-conductive dielectric layer are stretchable.

3. The method of claim 1, wherein one or more of the conductive layer or the non-conductive dielectric layer are flexible layers.

4. The method of claim 3, wherein the flexible layers are adapted to conform to at least one of a non-planar surface and the flexible layers are continually flexible.

5. The method of claim 1, wherein the conductive ink is cured or dried.

6. The method of claim 1, wherein the conductive ink is not solderable.

7. The method of claim 1, wherein the conductive ink comprises at least one of gold, silver, tin, aluminum, copper, nickel, and cobalt.

8. The method of claim 1, wherein the non-conductive dielectric layer includes at least one of a polymer film and a dielectric ink.

9. The method of claim 1, wherein applying the conductive ink forms one or more openings in the conductive layer, and wherein the non-conductive dielectric layer fills the one or more openings in the conductive layer.

10. The method of claim 1, wherein applying the conductive ink includes one or more of dispensing, flat bed screen printing, roll to roll screen printing, gravure printing, inkjet printing, aerosol jet printing, or flexography printing.

11. The method of claim 1, wherein applying the non-conductive dielectric layer includes one or more of laminating, dispensing, depositing, flat bed screen printing, roll to roll screen printing, gravure printing, inkjet printing, aerosol jet printing, or flexography printing.

12. The method of claim 1, wherein forming the contact pad in the opening in the non-conductive dielectric layer includes electrolytic plating, electroless plating, or applying solderable ink.

13. The method of claim 1, wherein forming the opening in the non-conductive dielectric layer includes one or more of mechanical drilling, laser drilling, or etching.

14. The method of claim 1, further comprises:
applying a solder paste to at least one of the contact pad and an electrical connection point of an electronic component;
placing the electrical connection point and the contact pad in a position adjacent to each other, wherein the solder paste engages each of the contact pad and the electrical connection point; and
heating the solder paste to electrically couple the electrical connection point to the contact pad.

15. The method of claim 14, wherein the solder paste is at least one of SnBi, SnBiAg, Sac305, and SAC105.

16. The method of claim 14, wherein applying the solder paste includes stencil printing, jet printing, or syringe depositing.

17. The method of claim 14, wherein heating the solder paste includes a reflow process.

18. The method of claim 1, wherein the non-conductive flexible substrate includes thermoplastic polyurethane (TPU), polydimethylsiloxane (PDMS), polyethylene terephthalate (PET), polyvinylchloride (PVC), polycarbonate (PC), polyethylene (PE), polypropylene (PP) or olefin.

19. An electronic device, comprising:
a first layer providing a non-conductive surface;
a second layer comprising a non-solderable conductive ink applied to selected portions of the first layer;
a third layer comprising a non-conductive dielectric applied to a selected portion of the first layer and to a selected portion of the second layer forming an opening, on a portion of the second layer, in the third layer; and
a fourth layer comprising a solderable conductive layer applied in the opening on the portion of the second layer.

20. An electronics assembly, comprising:
a non-conductive substrate;
a non-solderable conductive ink applied to selected portions of the non-conductive substrate to form a conductive layer;
a non-conductive dielectric layer applied to selected portions of the non-conductive substrate and selected portions of the conductive layer forming an opening, above a portion of the conductive layer, in the non-conductive dielectric layer;
a solderable conductive layer applied to the opening, above the conductive layer, in the non-conductive dielectric layer to form a contact pad on the portion of the conductive layer; and
an electronic component including an electrical connection point, wherein a solder paste is applied to at least one of the contact pad and the electrical connection point, wherein the electrical connection point and the contact pad are placed in a position adjacent to each other, wherein the solder paste engages each of the contact pad and the electrical connection point, and wherein the solder paste is heated to electrically couple the electrical connection point to the contact pad.
